(19) United States
(12) Patent Application Publication
(10) Pub. No.: US 2017/0372903 A1
(43) Pub. Date: Dec. 28, 2017

(54) METHOD FOR DOPING SEMICONDUCTORS

(71) Applicant: MERCK PATENT GMBH, DARMSTADT (DE)

(72) Inventors: Oliver DOLL, Dietzenbach (DE); Ingo KOEHLER, Darmstadt (DE); Sebastian BARTH, Darmstadt (DE)

(73) Assignee: MERCK PATENT GMBH, DARMSTADT (DE)

(21) Appl. No.: 15/540,618

(22) PCT Filed: Dec. 1, 2015
(86) PCT No.: PCT/EP2015/002412

§ 371 Date: Jun. 29, 2017

(30) Foreign Application Priority Data
Dec. 30, 2014 (EP) 14004453.8

(51) Int. Cl. H01L 21/22; H01L 31/18; H01L 31/0288

(52) U.S. Cl. CPC H01L 21/2225; H01L 31/0288; H01L 31/1804

(57) ABSTRACT

The present invention relates to a process for the production of structured, highly efficient solar cells and of photovoltaic elements which have regions of different doping. The invention likewise relates to the solar cells having increased efficiency produced in this way.

The present invention relates to a process and composition for the production of structured, highly efficient solar cells and of photovoltaic elements which have regions of different doping. The invention likewise relates to the solar cells having increased efficiency produced in this way.

### PRIOR ART

The production of simple solar cells or the solar cells which are currently represented with the greatest market share in the market comprises the essential production steps outlined below:

1) Saw-damage etching and texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface nature as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the solar cell.

The above-mentioned etching solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etching solution, the etching temperature and the residence time of the wafers in the etching tank. The texturing of the monocrystalline wafers is typically carried out in the temperature range from 70-less than 90° C., where up to 10 μm of material per wafer side can be removed by etching.

In the case of multicrystalline silicon wafers, the etching solution can consist of potassium hydroxide solution having a moderate concentration (10-15%). However, this etching technique is hardly still used in industrial practice. More frequently, an etching solution consisting of nitric acid, hydrofluoric acid and water is used. This etching solution can be modified by various additives, such as, for example, sulfuric acid, phosphoric acid, acetic acid, N-methylpyrrolidone, and also surfactants, enabling, inter alia, wetting properties of the etching solution and also its etching rate to be specifically influenced. These acidic etch mixtures produce a morphology of nested etching trenches on the surface. The etching is typically carried out at temperatures in the range between 4° C. and less than 10° C., and the amount of material removed by etching here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

2) Diffusion and doping

The wafers etched and cleaned in the preceding step (in this case p-type base doping) are treated with vapour consisting of phosphorus oxide at elevated temperatures, typically between 750° C. and less than 1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P₂O₅) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG and silicon wafer, where it is reduced to phosphorus by reaction with the silicon at the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon.

In this diffusion process, concentration gradients in the order of 10⁵ form between typical surface concentrations of 10²¹ atoms/cm² and the base doping in the region of 10¹⁶ atoms/cm². The typical diffusion depth is 250 to 500 nm and is dependent on the diffusion temperature selected, for example at about 880° C., and the total exposure duration (heating, coating phase, drive-in phase and cooling) of the wafers in the strongly warmed atmosphere. During the coating phase, a PSG layer forms which typically has a layer thickness of 40 to 60 nm. The coating of the wafers with the PSG, during which diffusion into the volume of the silicon also already takes place, is followed by the drive-in phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed.

During drive-in, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG, and the silicon wafer. The growth of this layer is very much faster in relation to the mass flow of the dopant from the source (PSG), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and drive-in phase is, for example, 25 minutes. After this treatment, the tubular furnace is automatically cooled, and the wafers can be removed from the process tube at temperatures between 600° C. and 700° C.

In the case of boron doping of the wafers in the form of n-type base doping, a different method is used, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors, more precisely to a crucial extent on the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon.

Thus, mention may be made of
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride),
purely thermal gas-phase deposition starting from solid dopant sources (for example boron oxide and boron nitride),
sputtering of boron onto the silicon surface and thermal drive-in thereof into the silicon crystal,
laser doping from dielectric passivation layers of different compositions, such as, for example, Al₂O₃, SiOₓN_{y}, where the latter contains the dopants in the form of admixed P₂O₅ and B₂O₃,
and liquid-phase deposition of liquids or pastes having a doping action.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant behind on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a through-flow furnace at temperatures between 800° C. and 1000° C., where the temperatures may be slightly increased compared with gas-phase diffusion in the tubular furnace in order to shorten the passage time. The gas atmosphere prevailing in the through-flow furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and drive-in of the dopant can in principle take place decoupled from one another.

3) Removal of the dopant source and optional edge insulation

The wafers present after the doping are coated on both sides with more or less glass on both sides of the surface. More or less in this case refers to modifications which can be applied during the doping process: double-sided diffusion compared with virtually single-sided diffusion promoted by back-to-back arrangement of two wafers in one location of the process boats used. The latter variant enables predominantly single-sided doping, but does not completely suppress diffusion on the back. In both cases, the current state of the art is removal of the glasses present after the doping from the surfaces by means of etching in dilute hydrofluoric acid. To this end, the wafers are on the one hand reloaded in batches into wet-process boats and with the aid of the latter dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG is achieved within 210 seconds at room temperature under these process conditions, for example using 2% hydrofluoric acid solution. The etching of corresponding BSGs is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etching solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (greater than 25° C. less than 50° C.).

In the process outlined last, it has become established to carry out the so-called edge insulation sequentially at the same time, giving rise to a slightly modified process flow:

edge insulation→glass etching.

Edge insulation is a technical necessity in the process which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell will have been short-circuited via a parasitic and residue p-n junction (tunnel contact), which reduces the conversion efficiency of the later solar cell. For removal of this junction, the wafers are passed on one side over an etching solution consisting of nitric acid and hydrofluoric acid. The etching solution may comprise, for example, sulfuric acid or phosphoric acid as secondary constituents. Alternatively, the etching solution is transported (conveyed) via rollers onto the back of the wafer. About 1 μm of silicon (including the glass layer present on the surface to be treated) is typically removed by etching in this process at temperatures between 4° C. and 8° C. In this process, the glass layer still present on the opposite side of the wafer serves as a mask, which provides a certain protection against overetching onto this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4) Coating of the front surface with an antireflection layer

After the etching of the glass and the optional edge insulation, the front surface of the later solar cells is coated with an antireflection coating, which usually consists of amorphous and hydrogen-rich silicon nitride. Alternative antireflection coatings are conceivable. Possible coatings may consist of titanium dioxide, magnesium fluoride, tin dioxide and/or corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, which can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of about 80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited in an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. and 400° C. Alternative deposition methods can be, for example, LPCVD and/or sputtering.

5) Production of the front surface electrode grid

After deposition of the antireflection layer, the front surface electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content greater than or equal to 80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a through-flow furnace. An furnace of this type generally has a plurality of heating zones which can be activated and temperature-controlled independently of one another.

During passivation of the through-flow furnace, the wafers are heated to temperatures up to about 950° C. However, the individual wafer is generally only subjected to this peak temperature for a few seconds. During the remainder of the through-flow phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. sections 6 and 7), which is why the term co-firing process is also used in this case.

The front surface electrode grid consists per se of thin fingers (typical number greater than or equal to 68 in the case of an emitter sheet resistance >50 Ω/sqr) which have a width of typically 60 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3, but can be increased significantly through the choice of alternative and/or adapted metallisation processes. An alternative metallisation process which may be mentioned is the dispensing of metal paste. Adapted metallisation processes are based on two successive screen-printing processes, optionally with two metal pastes of different composition (dual print or print-on-print). In particular in the case of the last-mentioned process, use can be made of so-called floating busbars, which guarantee dissipation of the current from the fingers collecting the charge carriers, but which do are not in direct ohmic contact with the silicon crystal itself.

6) Production of the back surface busbars

The back surface busbars are generally likewise applied and defined by means of screen-printing processes. To this end, a similar silver paste to that used for the front surface metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and compacted and sintered as already described in section 5.

7) Production of the back surface electrode

The back surface electrode is defined after the printing of the busbars. The electrode material consists of aluminium, which is why an aluminium-containing paste is printed onto the remaining free area of the wafer back by means of screen printing with an edge separation less than 1 mm for definition of the electrode. The paste is composed of greater than or equal to 80% of aluminium. The remaining components are those which have already been mentioned under section 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom per cent), where the silicon is p⁺-doped as a consequence of this drive-in. During cooling of the wafer, a eutectic mixture of aluminium and silicon, which solidifies at 577° C. and has a composition having a mole fraction of 0.12 of Si, deposits, inter alia, on the wafer surface.

As a consequence of the drive-in of aluminium into the silicon, a highly doped p-type layer, which functions as a type of mirror (“electric mirror”) on parts of the free charge carriers in the silicon, forms on the back of the wafer.

These charge carriers cannot overcome this potential wall and are thus kept away from the back wafer surface very efficiently, which is thus evident from an overall reduced recombination rate of charge carriers at this surface. This potential wall is generally referred to as “back surface field”.

The sequence of the process steps which have been described in sections 5, 6 and 7 may correspond to the sequence outlined here. However, this is not absolutely necessary. It is evident to the person skilled in the art that the sequence of the outlined process steps can in principle be carried out in any conceivable combination.

8) Optional edge insulation

If the edge insulation of the wafer has not already been carried out as described under point 3, this is typically carried out with the aid of laser-beam methods after the co-firing. To this end, a laser beam is directed at the front of the solar cell, and the front surface p-n junction is parted with the aid of the energy coupled in by this beam. Cut trenches having a depth of up to 15 μm are generated here as a consequence of the action of the laser. Silicon is removed from the treated site via an ablation mechanism or ejected from the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is aware of solar-cell architectures with both n-type and also p-type base material. These solar cell types include
PERC solar cells
PERT solar cells
PERL solar cells
MWT solar cells
MWT-PERC, MWT-PERT and MWT-PERL solar cells derived therefrom
bifacial solar cells having a homogeneous and selective back surface field
back surface contact cells
back surface contact cells with interdigital contacts.

The choice of alternative doping technologies, as an alternative to the gas-phase doping already described in the introduction, is generally also unable to solve the problem of the production of regions with locally different doping on the silicon substrate. Alternative technologies which may be mentioned here are the deposition of doped glasses, or of amorphous mixed oxides, by means of PECVD and APCVD processes. Thermally induced doping of the silicon located under these glasses can easily be achieved from these glasses. However, in order to create regions with locally different doping, these glasses must be etched by means of mask processes in order to prepare the corresponding structures from these. Alternatively, structured diffusion barriers can be deposited on the silicon wafers prior to the deposition of the glasses in order thus to define the regions to be doped. However, it is disadvantageous in this process that in each case only one polarity (n or p) of the doping can be achieved. Somewhat simpler than the structuring of the doping sources or of any diffusion barriers is direct laser beam-supported drive-in of dopants from dopant sources deposited in advance on the wafer surfaces. This process enables expensive structuring steps to be saved. Nevertheless, the disadvantage of possibly desired simultaneous doping of two polarities on the same surface at the same time (co-diffusion) cannot be compensated for, since this process is likewise based on pre-deposition of a dopant source which is only activated subsequently for the release of the dopant. A disadvantage of this (post)doping from such sources is the unavoidable laser damage of the substrate: the laser beam must be converted into heat by absorption of the radiation. Since the conventional dopant sources consist of mixed oxides of silicon and the dopants to be driven in, i.e. of boron oxide in the case of boron, the optical properties of these mixed oxides are consequently fairly similar to those of silicon oxide. These glasses (mixed oxides) therefore have a very low absorption coefficient for radiation in the relevant wavelength range. For this reason, the silicon located under the optically transparent glasses is used as absorption source. The silicon is in some cases warmed here until it melts, and consequently warms the glass located above it. This facilitates diffusion of the dopants—and does so a multiple faster than would be expected at normal diffusion temperatures, so that a very short diffusion time for the silicon arises (less than 1 second). The silicon is intended to cool again relatively quickly after absorption of the laser radiation as a consequence of the strong dissipation of the heat into the remaining, non-irradiated volume of the silicon and solidify epitactically on the non-molten material. However, the overall process is in reality accompanied by the formation of laser radiation-induced defects, which may be attributable to incomplete epitactic solidification and thus the formation of crystal defects. This can be attributed, for example, to dislocations and formation of vacancies and flaws as a consequence of the shock-like progress of the process. A further disadvantage of laser beam-supported diffusion is the relative inefficiency if relatively large areas are to be doped quickly, since the laser system scans the surface in a dot-grid process. This disadvantage naturally has less weight in the case of narrow regions to be doped. However, laser doping requires sequential deposition of the post-treatable glasses.

### OBJECT OF THE PRESENT INVENTION

The object of the present invention consists in providing a process and composition for the production of more-efficient solar cells which improve the current yield from the light incident on the solar cells and the charge carriers generated thereby in the solar cell. In this connection, inexpensive structuring is desirable, enabling the achievement of improved competitiveness compared with doping processes that are currently technologically predominant.

### BRIEF DESCRIPTION OF THE INVENTION

The present invention relates to a novel process for the direct doping of a silicon substrate in which

a) a doping paste which is suitable as sol-gel for the formation of oxide layers and comprises at least one doping element selected from the group boron, gallium, silicon, germanium, zinc, tin, phosphorus, titanium, zirconium, yttrium, nickel, cobalt, iron, cerium, niobium, arsenic and lead is printed onto the substrate surface, over the entire surface or selectively, and dried,

b) this step is optionally repeated with a doping paste of the same or different composition, and

c) doping by diffusion is optionally carried out by temperature treatment at temperatures in the range from 750 to 1100° C., and

d) doping of the substrate is carried out by laser irradiation, and

e) repair of the damage induced in the substrate by the laser irradiation is optionally carried out by a tubular furnace step or in-line diffusion step at elevated temperature, and

f) when the doping is complete, the glass layer formed from the applied paste is removed again,

where steps b) to e) can, depending on the desired doping result, be carried out in a different sequence and optionally repeated. The temperature treatment in the diffusion step after laser irradiation is preferably carried out at temperatures in the range from 750 to 1100° C. for the doping, where repair of the damage induced in the substrate by the laser irradiation is carried out at the same time.

In particular, however, the present invention also relates to a process as characterised by claims 2 to 9, which thus represent part of the present description.

In particular, however, the present invention also relates to the solar cells and photovoltaic elements produced by these process steps, which, owing to the process described here, have significantly improved properties, such as better light yield and thus improved efficiency, i.e. higher current yield.

### DETAILED DESCRIPTION OF THE INVENTION

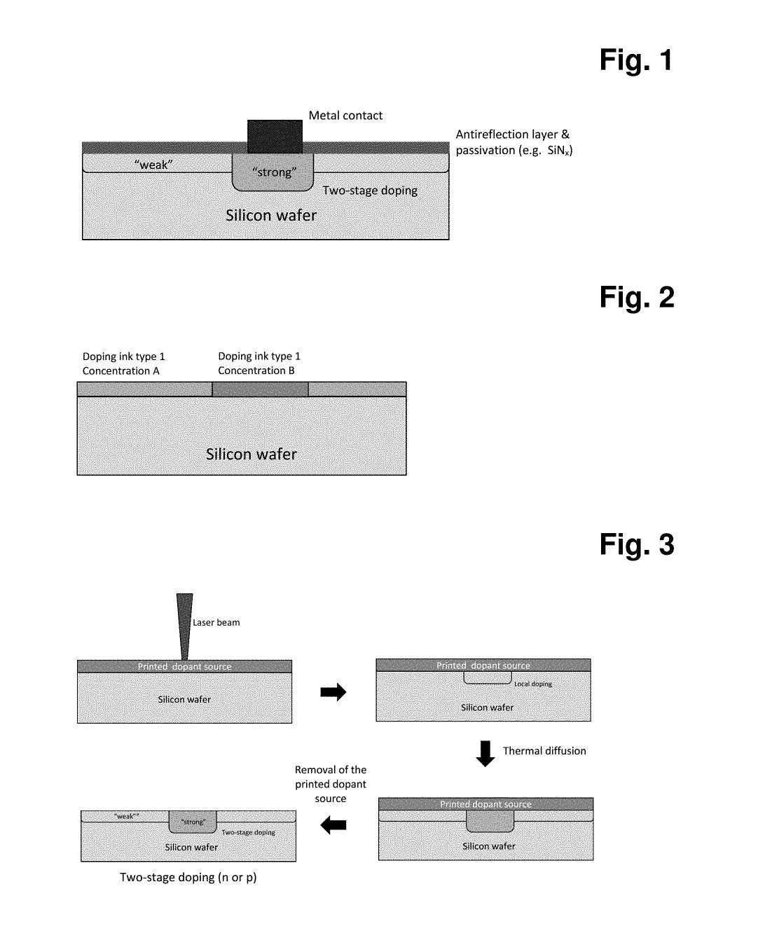

In principle, the increase in charge-carrier generation improves the short-circuit current of the solar cell. Although the possibility of improving the performance compared with conventional solar cells owing to many technological advances still appears to exist to the person skilled in the art, it is, however, no longer extraordinary, since the silicon substrate, even as indirect semiconductor, is capable of absorbing the predominant proportion of the incident solar radiation. A significant increase in the current yield is only still possible using, for example, solar-cell concepts which concentrate the solar radiation. A further parameter which characterises the performance of the solar cell is the so-called open terminal voltage or simply the maximum voltage that the cell is able to deliver. The level of this voltage is dependent on several factors, inter alia the maximum achievable short-circuit current density, but also the so-called effective charge-carrier lifetime, which is itself a function of the material quality of the silicon, but also a function of the electronic passivation of the surfaces of the semiconductor. In particular, the two last-mentioned properties and parameters play an essential role in the design of highly efficient solar-cell architectures and were originally amongst the main factors responsible for the possibility of increasing the performance in novel types of solar cell. Some novel types of solar cell were already mentioned in the introduction. Going back to the concept of the so-called selective or two-stage emitter (cf. FIG. 1), the principle can be outlined diagrammatically as follows with reference to its mechanism hiding behind the increase in efficiency, with reference to FIG. 1:

FIG. 1 shows a diagrammatic and simplified representation (not to scale) of the front of a conventional solar cell (back ignored). The figure shows the two-stage emitter, which arises from two doped regions, in the form of different sheet resistances. The different sheet resistances are attributable to different profile depths of the two doping profiles, and are thus generally also associated with different doses of dopants. The metal contacts of the solar cells to be manufactured from such structural elements are always in contact with the more strongly doped regions.

The front of the solar cell, at least generally, is provided with the so-called emitter doping. This can be either n-type or p-type, depending on the base material used (the base is then doped in the opposite manner). The emitter, in contact with the base, forms the pn junction, which is able to collect and separate the charge carriers forming in the solar cell via an electric field present over the junction. The minority charge carriers here are driven from the base into the emitter, where they then belong to the majorities. These majorities are transported further in the emitter zone and can be transported out of the cell as current via the electrical contacts located on the emitter zone. A corresponding situation applies to the minorities, which are generated in the emitter and can be transported away via the base. In contrast to the minorities in the base, these have a very short effective carrier lifetime of in the region of up to only a few nanoseconds in the emitter. This arises from the fact that the recombination rate of the minorities is in simplified terms inversely proportional to the doping concentration of the respective region in the silicon; i.e. the carrier lifetime of the respective minorities in the emitter region of a solar cell, which itself represents a highly doped zone in the silicon, can be very short, i.e. very much shorter than in the base, which is doped to a relatively low extent. For this reason, the emitter regions of the silicon wafer are, if possible, made relatively thin, i.e. have little depth in relation to the thickness of the substrate as a whole, in order that the minorities generated in this region, which then have a very short lifetime, which is inherent in the system, have sufficient opportunity, or indeed time, to achieve the pn junction and to be collected and separated at the latter and then driven into the base as majorities. The majorities generally have a carrier lifetime which should be regarded as infinite. If it is desired to make this process more efficient, the emitter doping and depth then inevitably have to be reduced in order that more minorities having a longer carrier lifetime can be generated and driven into the base as majorities transporting the current. Conversely, the emitter screens the minorities from the surface. The surfaces of a semiconductor are always very recombination-active. This recombination activity can be reduced very greatly (by up to seven orders of magnitude, measured from the effective surface recombination rate compared with a surface which has, for example, not been passivated) by the creation and deposition of electronic passivation layers.

The creation of an emitter having a sufficiently steep doping profile supports passivation of the surface in one aspect:

The carrier lifetime of the minorities in these regions becomes so short that their average lifetime only allows an extremely low quasi-static concentration. Since the recombination of charge carriers is based on the bringing together of minorities and majorities, simply too few minorities which are able to recombine with majorities directly at the surface are present in this case.

Significantly better electronic passivation than that of an emitter is achieved by means of dielectric passivation layers. On the other hand, however, the emitter is still partially responsible for the creation of the electrical contacts to the solar cell, which must be ohmic contacts. They are obtained by driving the contact material, generally silver, into the silicon crystal, where the so-called silicon—silver contact resistance is dependent on the level of doping of the silicon at the surface to be contacted. The higher the doping of the silicon, the lower the contact resistance can be. The metal contacts on the silicon are likewise very strongly recombination-active, for which reason the silicon zone below the metal contacts should have very strong and very deep emitter doping. This doping screens the minorities from the metal contacts, and at the same time a low contact resistance and thus very good ohmic conductivity are achieved.

By contrast, in all locations where the incident sunlight falls directly on the solar cell, the emitter doping should be very low and relatively flat (i.e. not very deep) in order that sufficient minorities having a sufficient lifetime can be generated by the incident solar radiation and driven into the base as majorities via separation at the pn junction.

Surprisingly, experiments have now shown that a solar cell which has two different emitter dopings, more precisely one region having shallow doping and one region having very deep and very high doping, which lie directly below the metal contacts has significantly higher efficiencies. This concept is referred to as a selective or two-stage emitter. The corresponding concept is based on so-called selective back surface fields. Consequently, two differently doped regions must be achieved in dopings structured at the surface of the solar cell.

The experiments have shown that the present object can be achieved, in particular, by achieving these structured dopings. The doping processes described in the introduction are generally based on shallow deposition and likewise shallow drive-in of the deposited dopant. Selective triggering in order to achieve different doping strengths is generally not provided and also cannot readily be achieved in the absence of further structuring and mask processes.

Accordingly, the present process consists in a simplified production process compared with the two-stage or selective emitter structures described above. More generally, the process describes a simplification of the production of zones doped with different strengths and depths (n and p) starting from the surface of a silicon substrate, where the term “strength” can, but does not necessarily have to, describe the level of the achievable surface concentration. This may be the same in both cases in the case of zones doped in two stages. The different strength of the doping then arises via the different penetration depth of the dopant and the associated different integral doses of the respective dopant. The process described here thus at the same time provides an inexpensive and simplified production of solar cell structures having at least one structural motif which has two-stage doping. Corresponding solar cell structures are as already referred to earlier.
PERC solar cells
PERT solar cells
PERL solar cells
MWT solar cells
MWT-PERC, MWT-PERT and MWT-PERL solar cells derived therefrom
bifacial solar cells having a homogeneous and selective back surface field
back surface contact cells
back surface contact cells with interdigital contacts.

The simplified production process is made possible by the use of doping media which can be printed simply and inexpensively. The doping media correspond at least to those disclosed in the patent applications WO 2012/119686 A1 and WO 2014/101989 A1, but may have different compositions and formulations.

The doping media have a viscosity of preferably greater than 500 mPa*s, measured at a shear rate of 25 1/s and a temperature of 23° C., and are thus, owing to their viscosity and their other formulation properties, extremely well adapted to the individual requirements of screen printing. They are pseudo-plastic and may furthermore also have thixotropic behaviour. The printable doping media are applied to the entire surface to be doped with the aid of a conventional screen-printing machine. Typical, but non-restrictive print settings are mentioned in the course of the present description. The printed doping media are subsequently dried on in a temperature range between 50° C. and 750° C., preferably between 50° C. and 500° C., particularly preferably between 50° C. and 400° C., using one or more heating steps to be carried out sequentially (heating by means of a step function) and/or a heating ramp and compacted for vitrification, resulting in the formation of a handling- and abrasion-resistant layer having a thickness of up to 500 nm. The further processing in order to achieve two-stage dopings of the substrates treated in this way may subsequently comprise two possible process sequences, which will be outlined briefly below.

The process sequence will be described exclusively for the possible doping of the silicon substrate with boron as dopant. Analogous descriptions, albeit deviating slightly in the necessity of carrying them out, can also be applied to phosphorus as dopant.
1. Heat treatment of the layers printed onto the surfaces, compacted and vitrified is carried out at a temperature in the range between 750° C. and 1100° C., preferably between 850° C. and 1100° C., particularly preferably between 850° C. and 1000° C. As a consequence, atoms having a doping action on silicon, such as boron, are released to the substrate by silicothermal reduction of their oxides (so long as the dopants are present in the form of free and/or bound oxides in the matrix of the dopant source) on the substrate surface, whereby the conductivity of the silicon substrate is specifically advantageously influenced as a consequence of the doping commencing. It is particularly advantageous here that, owing to the heat treatment of the printed substrate, the dopants are transported to depths of up to 1 μm, depending on the treatment duration, and electrical sheet resistances of less than 10 Ω/sqr are achieved. The surface concentration of the dopant can adopt values greater than or equal to 1*10¹⁹ to greater than 1*10²¹ atoms/cm³ here and is dependent on the type of dopant used in the printable oxide medium. In the case of doping with boron, a thin so-called boron skin, which is generally regarded as a phase consisting of silicon boride which forms as soon as the solubility limit of boron in silicon is exceeded (this is typically 3-4*10²⁰ atoms/cm³), forms on the silicon surface. The formation of this boron skin is dependent on the diffusion conditions used, but cannot be prevented within the bounds of classical gas-phase diffusion and doping. However, it has been found that the choice of the formulation of the printable doping media enables a considerable influence to be exerted on the formation and the formed thickness of the boron skin. The boron skin present on the silicon substrate can be used by means of suitable laser irradiation as dopant source for the locally selective further drive-in of the dopant boron which deepens the doping profile. To this end, however, the wafers treated in this way must be removed from the diffusion and doping furnace and treated by means of laser irradiation. At least the silicon wafer surface regions remaining and not exposed to the laser irradiation subsequently still have an intact boron skin. Since the boron skin has in numerous investigations proven to be counterproductive for the electronic surface passivation ability of the silicon surfaces, it appears essential to eliminate it in order to prevent disadvantageous diffusion and doping processes.
   The successful elimination of this phase can be achieved by means of various oxidative processes, such as, for example, low-temperature oxidation (typically at temperatures between 600° C. and 850° C.), a brief oxidation step below the diffusion and doping temperature in which the gas atmosphere is adjusted in a specific and controlled manner by enrichment of oxygen, or by the constant drive-in of a small amount of oxygen during the diffusion and doping process.
   The choice of oxidation conditions influences the doping profile obtained: in the case of low-temperature oxidation, exclusively the boron skin is oxidised at a sufficiently low temperature, and only slight surface depletion of the dopant boron, which in principle dissolves better in the silicon dioxide formed during the oxidation, takes place, while not only exclusively the boron skin, but also parts of the doped silicon actually desired, which, owing to the high doping, has a significantly increased oxidation rate (increase in the rate by a factor of up to 200) is also oxidised and consumed in the remaining two oxidation steps. Significant depletion of the dopant can take place at the surface, which requires thermal after-treatment, a distribution or drive-in step of the dopant atoms which have already diffused into the silicon. However, in this case the dopant source presumably supplies only little or no further dopant to the silicon. The oxidation of the silicon surface and of the boron skin present thereon can also be carried out and significantly accelerated by the additional introduction of steam and/or chlorine-containing vapours and gases. An alternative method for elimination of the boron skin consists in wet-chemical oxidation by means of concentrated nitric acid and subsequent etching of the silicon dioxide layer obtained on the surface. This treatment must be carried out in a plurality of cascades for complete elimination of the boron skin, where this cascade is not accompanied by significant surface depletion of the dopant.
   The sequence outlined here for the production of regions with locally selective or two-stage doping is distinguished by the following at least ten steps:
   Printing of the dopant source→
   Compaction→
   Introduction into doping furnace→
   Thermal diffusion and doping of the substrate→
   Removal of the samples→
   Laser irradiation for selective doping from the boron skin→
   Introduction of the samples into the furnace→
   Oxidative removal of the boron skin→
   Further drive-in treatment→
   Removal from the furnace.
2. The drying and compaction of the dopant applied over the entire surface is followed by local irradiation of the substrate by means of laser radiation. To this end, the layer present on the surface does not necessarily have to be completely compacted and vitrified. Through a suitable choice of the parameters characterising the laser radiation treatment, such as pulse length, illuminated area in the radiation focus, repetition rate on use of pulsed laser radiation, the printed-on and dried-on layer of the dopant source can release the dopants having a doping action which are present therein to the surrounding silicon, which is preferably located below the printed-on layer. Through the choice of the laser energy coupled onto the surface of the printed substrate, the sheet resistance of the substrate can be specifically influenced and controlled. Higher laser energies here give rise to lower sheet resistance, which, in simplified terms, corresponds to a higher dose of the introduced dopant and a greater depth of the doping profile. If necessary, the printed-on layer of the dopant source can subsequently be removed from the surface of the wafer without a residue with the aid of aqueous solutions containing both hydrofluoric acid and also hydrofluoric acid and phosphoric acid or by means of corresponding solutions based on organic solvents, and also through the use of mixtures of the two above-mentioned etching solutions. The removal of the dopant source can be accelerated and promoted by the action of ultrasound during the use of the etching mixture. Alternatively, the printed-on dopant source can be left on the surface of the silicon wafer. The wafer coated in this way can be doped on the entire coated silicon wafer surface by thermally induced diffusion in a conventional doping furnace. This doping can be carried out in doping furnaces usually used. These can be either tubular furnaces (horizontal and/or vertical) or horizontally working through-flow furnaces, in which the gas atmosphere used can be set specifically. As a consequence of the thermally induced diffusion of the dopants from the printed-on dopant source into the underlying silicon of the wafer, doping of the entire wafer is achieved in combination with a change in the sheet resistance. The degree of doping is dependent on the respective process parameters used, such as, for example, process temperature, plateau time, gas flow rate, the type of heating source used and the temperature ramps for setting the respective process temperature. In a process of this type, depending on the regions treated by means of laser beam doping and using a doping paste formulation according to the invention, sheet resistances of about 75 ohm/sqr are usually achieved at a diffusion time of 30 minutes at 950° C. and with a gas flow rate of five standard litres of N₂ per minute. In the case of the treatment mentioned above, the wafers can optionally be pre-dried at temperatures of up to 500° C. The diffusion is followed directly, as already described in greater detail above under 1), by oxidative removal of the so-called boron skin, but also optionally redistribution of the boron dissolved in the silicon for adaptation and manipulation of the doping profile which can be established. The above-mentioned sheet resistance can be obtained reproducibly, based on the procedure just outlined. Further details on the performance and corresponding further process parameters are described in greater detail in the following examples.
   The regions already defined previously by means of laser beam treatment and the dopants dissolved in these regions are likewise stimulated to further diffusion as a consequence of the thermally induced diffusion of the dopants. Owing to this additional diffusion, the dopants are able to penetrate deeper into the silicon at these points and accordingly shape a deeper doping profile. At the same time, dopant can subsequently be supplied to the silicon from the dopant source located on the wafer surface. Doped zones which have a significantly deeper doping profile and also a significantly higher dose of the dopant boron than those regions which were subjected to thermally induced diffusion exclusively in a doping furnace thus form in the regions which were previously subjected to the laser radiation treatment. In other words, two-stage dopings, also known as selective dopings, arise. The latter can be used, for example, in the production of solar cells having a selective emitter, in the production of bifacial solar cells (having a selective emitter/uniform (one-stage) BSF, having a uniform emitter/selective BSF and having a selective emitter/selective BSF), in the production of PERT cells, or also in the production of IBC solar cells.
   The comparable principle also applies to the thermally induced post-diffusion of silicon wafers which have been pretreated by means of laser radiation, which were previously freed from the presence of the printed-on dopant source by means of etching. In this case, the dopant boron is driven deeper into the silicon. Owing to the removal of the printed-on dopant source which took place before this process, however, dopant can no longer subsequently be supplied to the silicon. The dose dissolved in the silicon will remain constant, while the average concentration of the dopant in the doped zone is reduced owing to increasing profile depth and associated reduction in the direct surface concentration of the dopant. This procedure can be used for the production of IBC solar cells. Strips of one polarity are generated from the dried-on doping paste by means of laser beam doping alongside strips having the opposite polarity, which can in turn be obtained with the aid of laser beam doping from a printed-on and dried-on phosphorus-containing doping paste. The sequence thus outlined for the production of regions with locally selective or two-stage doping is distinguished by the following at least eight steps:
   Printing of the dopant source→
   Drying→
   Laser irradiation from the dopant source→
   Introduction into the doping furnace→
   Thermal diffusion and (further) doping of the substrate→
   Oxidative removal of the boron skin→
   Further drive-in treatment→
   Removal of the samples from the furnace (cf. FIG. 3).

The two process cascades described above represent possibilities for the production of two-stage, or so-called selective, dopings. On the basis of the above-mentioned embodiments and the associated number of process steps to be carried out, the second embodiment described represents the alternative which is more attractive and to be preferred owing to the smaller number of process steps.

In both embodiments, the doping action of the printed-on dopant source can be influenced by the choice of the respective process parameters, in particular those of the laser beam treatment or laser beam doping. However, the doping action can also be crucially influenced and controlled by the composition of the printable dopant source (cf. FIG. 2). If desired, two-stage dopings can take place not exclusively only through the use of a printable dopant source followed by a further dopant source, but instead they can also be generated through the use of two printable dopant sources. The dose of dopants which is to be introduced into the silicon to be doped can, in particular, be specifically influenced and controlled by the above-mentioned embodiment via the dopant concentrations present in the dopant sources used.

FIG. 2 shows a diagrammatic and simplified representation (not to scale) of the doping process according to the invention induced by laser radiation treatment (cf. FIG. 3) of printable doping pastes on silicon wafers, where printable doping pastes of different compositions (such as, for example, doping pastes containing different concentrations of dopant) can be employed.

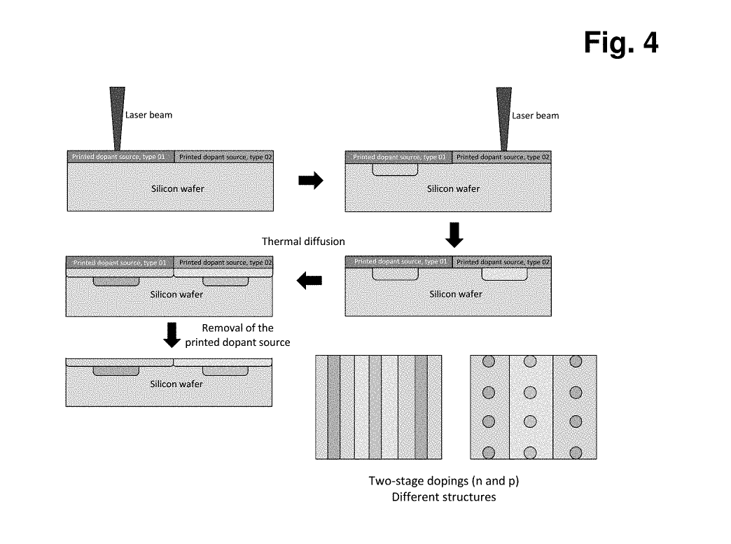

As described, both two-stage dopings and also structured dopings and dopings provided with opposite polarities can be produced very easily in a simple and inexpensive manner on silicon wafers by the process according to the invention using the novel printable doping pastes still to be characterised below, making in total only a single classical high-temperature step (thermally induced diffusion) necessary (cf. FIG. 4).

The opposite polarities may advantageously both be located on one side of a wafer, or on opposite sides, or finally represent a mixture of the two above-mentioned structural motifs. Furthermore, it is possible for both polarities to have two-stage doping regions, but they do not necessarily have to have both polarities. It is likewise possible to produce structures in which polarity 1 has a two-stage doping, while polarity 2 does not contain a two-stage doping. This means that the process described here can be carried out in a very variable manner. No further limits are set for the structures of the regions provided with opposite dopings, apart from the limits of the respective structure dissolution during the printing process and those which are inherent in the laser beam treatment. The representations of FIGS. 3, 4 and 5 depict various embodiments of the process according to the invention:

FIG. 3 shows a diagrammatic and simplified representation (not to scale) of the doping process according to the invention induced by laser radiation treatment of printable doping pastes on silicon wafers.

FIG. 4 shows a diagrammatic and simplified representation (not to scale) of the doping process according to the invention induced by laser radiation treatment of printable doping pastes on silicon wafers taking into account the generation of adjacent dopings of different polarities, which are in each case carried out in two stages (pale=weak doping, dark=stronger doping).

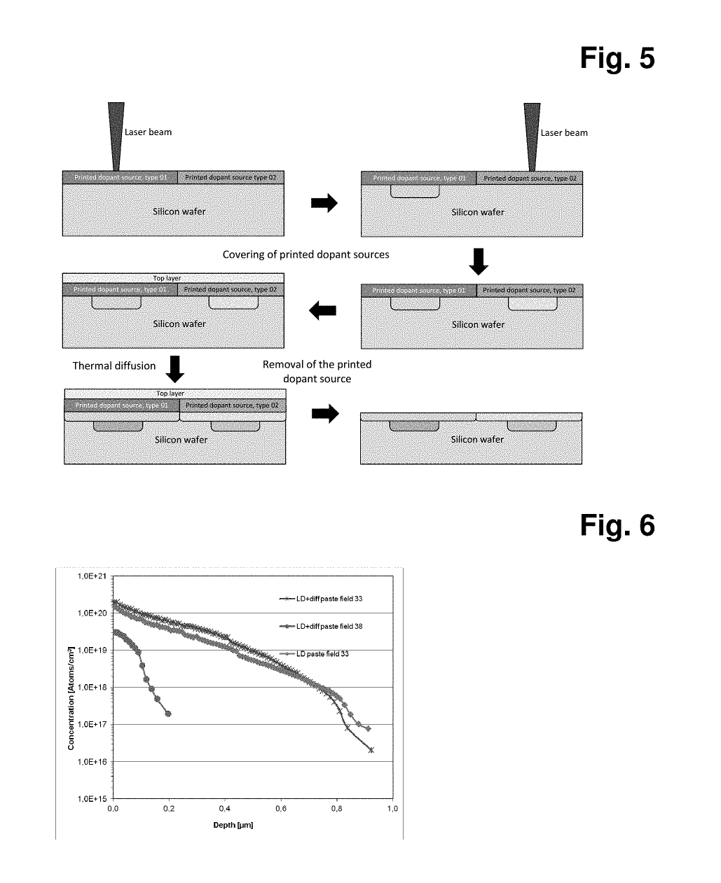

FIG. 5 shows a diagrammatic and simplified representation (not to scale) of the doping process according to the invention induced by laser radiation treatment of printable doping pastes on silicon wafers taking into account the generation of adjacent dopings of different polarities, which are in each case carried out in two stages (light=weak doping, dark=stronger doping). The printed and dried-on dopant sources can be sealed with possible top layers in one of the possible process variants. The top layers can be applied to the printed and dried-on dopant sources, inter alia both after the laser beam treatment and also before it. In the present FIG. 5, the top layer has been supplemented with the printed and dried-on dopant source by thermal diffusion after the laser beam treatment.

The present invention thus encompasses an alternative inexpensive process which can be carried out simply for the production of solar cells with more effective charge generation, but also the production of alternative, printable dopant sources which can be produced inexpensively, deposition thereof on the silicon substrate, and selective one-stage and also selective two-stage doping thereof.

The selective doping of the silicon substrate can, but does not necessarily have to, be achieved here by means of a combination of initial laser beam treatment of the printed and dried-on dopant source and subsequent thermal diffusion. The laser beam treatment of silicon wafers may be associated with damage to the substrate itself and thus represents an inherent disadvantage of this process inasmuch as this damage, which in some cases extends deep into the silicon, cannot be at least partially repaired by subsequent treatment. In the present process, the laser beam treatment may be followed by thermal diffusion, which contributes to repair of the radiation-induced damage. Furthermore, the metal contacts (cf. FIG. 1) in this type of production of structures doped in two stages are deposited directly on the regions exposed to the laser radiation. The silicon-metal interface is generally characterised by a very high recombination rate (in the order of 2*10⁷ cm/s), meaning that possible damage in the strongly doped zone of the region doped in two stages is not significant for the performance of the component as a consequence of the superordinate limiting of the charge-carrier lifetime on the metal contact.

Surprisingly, it has thus been found that the use of printable doping pastes, as described in the patent applications WO 2012/119686 A1 and WO 2014/101989 A1, provides the possibility of directly doping silicon substrates by laser beam treatment of a printed-on and dried-on medium.

This doping can be achieved locally and without further activation of the dopants, as is usually achieved by classical thermal diffusion. In a subsequent step, conventional thermal diffusion, the dopant introduced into the silicon can either be driven in deeper or the dopant already dissolved can be driven in deeper and further dopant can subsequently be transferred from the dopant source into the silicon, in the latter case causing an increase in the dose of the dopant dissolved in the silicon.

The dopant source printed onto the wafer and dried can have a homogeneous dopant concentration. This dopant source can, for this purpose, be applied to the entire surface of the wafer or printed on selectively. Alternatively, dopant sources of different compositions and different polarities can be printed onto the wafer in any desired sequence. To this end, the sources can, for example, be processed in two successive printing and drying steps.

The preferred embodiments of the present invention are reproduced in the following examples.

As stated above, the present description enables the person skilled in the art to use the invention comprehensively. Even without further comments, it will therefore be assumed that a person skilled in the art will be able to utilise the above description in the broadest scope.

Should anything be unclear, it goes without saying that the cited publications and patent literature should be consulted. Accordingly, these documents are regarded as part of the disclosure content of the present description. This applies, in particular, to the disclosure content of patent applications WO 2012/119686 A1 or WO 2014/101989 A1, since the compositions described in these applications are particularly suitable for use in the present invention.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

Furthermore, it goes without saying to the person skilled in the art that, both in the examples given and also in the remainder of the description, the component amounts present in the compositions always only add up to 100% by weight, mol-% or % by vol., based on the entire composition, and cannot exceed this, even if higher values could arise from the percent ranges indicated. Unless indicated otherwise, % data are therefore regarded as % by weight, mol-% or % by vol.

The temperatures given in the examples and the description and in the claims are always in ° C.

### EXAMPLES

### Example 1

A textured 6″ CZ wafer with phosphorus base doping, having a resistivity of 2 ohm*cm, is printed with a boron doping paste, as described in the patent applications WO 2012/119686 A1 and WO 2014/101989 A1, using a steel screen (mounting angle)22.5° having a wire diameter 25 μm and an emulsion thickness of 10 μm using a doctor-blade speed of 110 mm/s, a doctor-blade pressure of 1 bar and a printing screen separation of 1 mm, where, depending on the other printing parameters, a layer thickness between 100 nm and 400 nm becomes established after complete drying at 600° C. After printing, the printed-on paste is dried for three minutes at 300° C. on a conventional laboratory hotplate. The wafer is then treated in predefined fields with the aid of an Nd:YAG nanosecond laser having a wavelength of 532 nm and using various laser fluences acting on the dried-on dopant source. The dopings of the various fields on the wafer are subsequently determined with the aid of four-point measurements and electrochemical capacitance-voltage measurements (ECV). The wafer is subsequently subjected to thermal diffusion in a conventional tubular furnace using an inert-gas atmosphere, N₂, at 930° C. for 30 minutes. The boron skin formed during the boron diffusion is oxidised after the diffusion, but still during the furnace process, by means of dry oxidation at a constant process temperature and by controlled tilting as a consequence of the introduction of 20% by vol. of O₂ into the process chamber. After this process step, the sample wafer is freed from glass and oxide layers located on the wafer with the aid of dilute hydrofluoric acid and the doping action is characterised again by means of four-point measurements and electrochemical capacitance-voltage measurements (ECV). The sheet resistances of the doped samples are (in the sequence of their appearance in the representation of FIG. 6—the sheet resistance of the base-doped wafer is 160 ohm/sqr, the sheet resistance of a sample field which has been printed exclusively with the paste, but has not been exposed to the laser radiation, is 80 ohm/sqr):

TABLE 1
Summary of measured sheet resistances as a function of
different process procedures: after laser diffusion and
after laser diffusion and subsequent thermal diffusion.

| Processing | Sheet resistance [ohm/sqr] |
|---|---|
| Laser diffusion & thermal | 48 |
| diffusion, field 33 (LD & diff. ink, | |
| 33), 66% overlap of adjacent | |
| laser dots, energy density: 2.8 J/cm² | |
| Laser diffusion & thermal | 58 |
| diffusion, field 38 (LD & diff. ink, | |
| 38), 20% overlap of adjacent | |
| laser dots, energy density: 1.53 J/cm² | |
| Laser diffusion, field 33 (LD ink, | 70 |
| 33), 66% overlap of adjacent | |
| laser dots, energy density: 2.8 J/cm² | |

FIG. 6 shows ECV doping profiles as a function of various diffusion conditions: after laser diffusion and after laser diffusion and subsequent thermal diffusion. As a consequence of the laser irradiation of the printed-on and dried-on doping paste, doping of the silicon wafer has been induced, as can clearly be shown with reference to the measured values with reference to the doping profile in irradiated field 33 (LD, 33).

It can be shown, with reference to the determinations of the sheet resistances of fields which have been irradiated depending on different energy densities of the laser light, that dopings which do not require subsequent activation by means of thermal diffusion are already achieved from the printed and dried-on doping paste at a laser fluence of 1.1 J/cm². Thermal diffusion following the laser irradiation causes only a slight dip in the doping profile achieved by the laser irradiation, which is associated with a reduction in the sheet resistance. Treatment with a high energy density of the incident laser light, greater than 2 J/cm², produces very deep and very strongly doped regions.

1. Process for the direct doping of a silicon substrate, characterised in that
a) a doping paste which is suitable as sol-gel for the formation of oxide layers and comprises at least one doping element selected from the group boron, gallium, silicon, germanium, zinc, tin, phosphorus, titanium, zirconium, yttrium, nickel, cobalt, iron, cerium, niobium, arsenic and lead is printed onto the substrate surface, over the entire surface or selectively, and dried,
b) this step is optionally repeated with a doping paste of the same or different composition,
c) doping by diffusion is optionally carried out by temperature treatment at temperatures in the range from 750 to 1100° C.,
d) doping of the substrate is carried out by laser irradiation,
and
e) repair of the damage induced in the substrate by the laser irradiation is optionally carried out by a tubular furnace step or in-line diffusion step at elevated temperature,
and
f) when the doping is complete, the glass layer formed from the applied paste is removed again,
where steps b) to e) can, depending on the desired doping result, be carried out in a different sequence and optionally repeated.

2. Process according to claim 1, characterised in that a temperature treatment is carried out at temperatures in the range from 750 to 1100° C. for the doping by diffusion after laser irradiation for doping of the substrate, where repair of the damage induced in the substrate by the laser irradiation is carried out at the same time.

3. Process according to claim 1, characterised in that a doping paste which is suitable for the formation of oxide layers and comprises at least one doping element selected from the group boron, phosphorus, antimony, arsenic and gallium is printed on.

4. Process according to claim 1, characterised in that the doping paste is printed on by a printing process selected from the group screen printing, flexographic printing, gravure printing, offset printing, microcontact printing, electrohydrodynamic dispensing, roller coating, spray coating, ultrasonic spray coating, pipe jetting, laser transfer printing, pad printing, flat-bed screen printing and rotation screen printing.

5. Process according to claim 1, characterised in that the doping paste is printed on by screen printing.

6. Process according to claim 1, characterised in that doping is carried out directly from the printed and dried-on glass after boron diffusion with exclusion of an oxidation process of the “boron skin”.

7. Process according to claim 1, characterised in that structured, highly efficient solar cells which have regions of different doping are produced by at least one two-stage doping with only one thermal diffusion or high-temperature treatment of the substrate.

8. Process according to claim 1, characterised in that a glass layer which comprises at least one doping element selected from the group boron, gallium, silicon, germanium, zinc, tin, phosphorus, titanium, zirconium, yttrium, nickel, cobalt, iron, cerium, niobium, arsenic and lead is generated on the substrate surface over the entire surface or selectively in step a) by gas-phase deposition by means of PECVD (plasma-enhanced chemical vapour deposition), APCVD (atmospheric pressure chemical vapour deposition), ALD (atomic layer deposition) or sputtering.

9. Process according claim 8, characterised in that the glass layer is removed by means of hydrofluoric acid when the doping is complete.

10. Solar cells, produced by a process according to claim 1.

11. Photovoltaic elements, produced by a process according to claim 1.
